(19) United States
(12) Patent Application Publication
(10) Pub. No.: US 2008/0239637 A1
(43) Pub. Date: Oct. 2, 2008

(54) DISPLAY DEVICE AND METHOD OF MANUFACTURING THE SAME

(75) Inventors: Un-Cheol SUNG, Anyang-si (KR); Jung-Yeon KIM, Hwaseong-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/933,406

(22) Filed: Oct. 31, 2007

(30) Foreign Application Priority Data
Mar. 28, 2007 (KR) 10-2007-0030353

(51) Int. Cl. H05K 5/00; H01J 9/24

(52) U.S. Cl. 361/681; 445/25

(57) ABSTRACT

A display device includes a display panel includes an organic light emitting diode (OLED), an encapsulation member covering the display panel, a first sealant disposed between the display panel and the encapsulation member and surrounding the organic light emitting diode, and a second sealant disposed between the first sealant and the organic light emitting diode and surrounding the organic light emitting diode.

### CROSS-REFERENCE TO RELATED APPLICATION

This application claims priority from and the benefit of Korean Patent Application No. 10-2007-0030353, filed on Mar. 28, 2007, which is hereby incorporated by reference for all purposes as if fully set forth herein.

### BACKGROUND OF THE INVENTION

1. Field of the Invention

The present invention relates to a display device and a manufacturing method thereof, and more particularly, to a display device that may provide enhanced durability and a manufacturing method thereof.

2. Discussion of the Background

Among the various types of display devices, the liquid crystal display (LCD) and the organic light emitting diode (OLED) display are small and light-weight and have improved in performance due in part to rapidly developing semiconductor technology. This is especially true of the organic light emitting diode display.

An organic light emitting diode display device may include a display panel having a thin film transistor (TFT) and an organic light emitting diode and an encapsulation panel facing and covering the display panel. The organic light emitting diode includes an organic layer, an anode electrode, and a cathode electrode. The encapsulation panel seals off the display panel.

However, moisture may enter the inside of the organic light emitting diode display device and permeate the organic layer. Accordingly, the performance of the organic light emitting diode may deteriorate. Also, the life span of the organic light emitting diode display device may decrease, and the quality of the organic light emitting diode display device may deteriorate.

A sealant may be used to adhere the encapsulation panel to the display panel and to protect the display panel from moisture. However, the sealant may be damaged when the adhered encapsulation panel and display panel are cut. Accordingly, the durability of the organic light emitting diode display device may deteriorate.

### SUMMARY OF THE INVENTION

The present invention provides a display device that may have enhanced durability.

The present invention also provides a method of manufacturing a display device that may have enhanced durability.

Additional features of the invention will be set forth in part in the description which follows, and in part will be obvious from the description, or may be learned by practice of the present invention.

The present invention discloses a display device including a display panel including an organic light emitting diode (OLED), an encapsulation member covering the display panel, a first sealant disposed between the display panel and the encapsulation member and surrounding the organic light emitting diode, and a second sealant disposed between the first sealant and the organic light emitting diode and surrounding the organic light emitting diode.

The present invention also discloses a display device manufacturing method including preparing a display panel including an organic light emitting diode (OLED), preparing an encapsulation member, and forming a first intermediate sealant and a second intermediate sealant on one of the display panel and the encapsulation member. The first intermediate sealant and the second intermediate sealant have loop shapes and one of the first intermediate sealant and the second intermediate sealant surrounds the other. The other of the display panel and the encapsulation member is adjoined to the first intermediate sealant and the second intermediate sealant and a first sealant and a second sealant are formed by providing the first intermediate sealant and the second intermediate sealant with energy from an energy source. The first sealant and the second sealant are adhered to the display panel and the encapsulation member.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a display device according to a first exemplary embodiment of the present invention.

FIG. 2 is a layout view of a display panel in FIG. 1.

FIG. 3 is an enlarged view of a display panel in FIG. 1.

FIG. 4, FIG. 5, and FIG. 6 are cross-sectional views showing a process of manufacturing the display device of FIG. 1.

FIG. 7 is a cross-sectional view of a display device according to a second exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

The accompanying drawings show an organic light emitting diode (OLED) display as a display device.

In addition, the accompanying drawings show an active matrix (AM)-type OLED having a 2Tr-1Cap structure in which one pixel may include two thin film transistors (TFTs) and one capacitor, but it is not limited thereto. Herein, the pixel is a minimum unit used to display an image.

Therefore, in the display device, one pixel may include more than three TFTs and more than two capacitors, and additional wiring may be further provided.

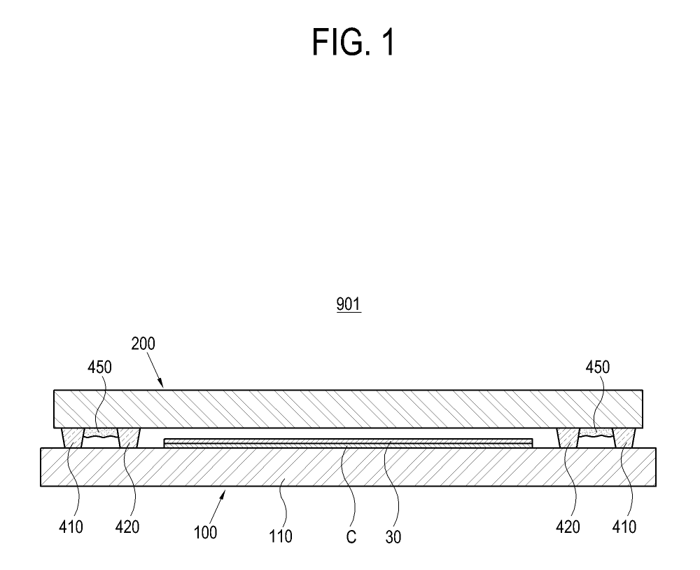

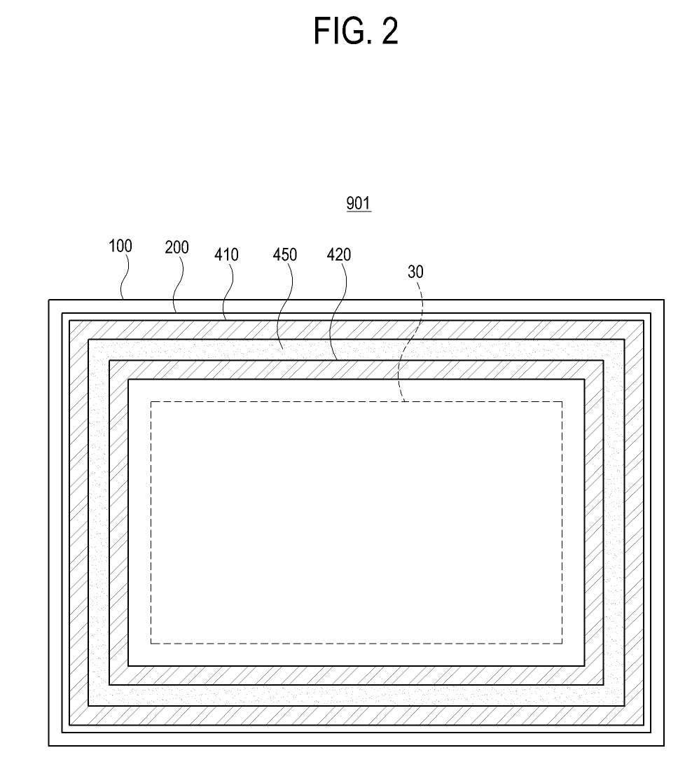

FIG. 1 is a cross-sectional view of a display device according to a first exemplary embodiment of the present invention, and FIG. 2 is a layout view of the display panel of FIG. 1.

As shown in FIG. 1, a display device 901 includes a display panel 100, an encapsulation member 200, a first sealant 410, and a second sealant 420. Also, the display device 901 further includes a desiccant member 450.

The display panel 100 includes a substrate member 110, a circuit-forming layer C formed on the substrate member 110, and an organic light emitting diode 30.

The substrate member 110 may be an insulating substrate made of glass, quartz, ceramic, or plastic. When the substrate member 110 is made of a material having flexibility, a utilization range of the display device 901 may be increased so that availability of the display device 901 can be further improved.

Although it is not shown in FIG. 1, the circuit-forming layer C may include various thin wires such as a gate line, a data line, a common power line, a thin film transistor connected to the thin wire, and a capacitor.

Although it is not shown in FIG. 1, the organic light emitting diode 30 may include a positive electrode connected to the thin film transistor of the circuit-forming layer C, an organic layer formed on the positive electrode, and a negative electrode formed on the organic layer. The positive electrode serves as a hole injection electrode. The negative electrode serves as an electron injection electrode.

Holes and electrons are respectively injected into the organic layer from the positive electrode and the negative electrode. The injected holes and electrons form excitons. When the energy state of excitons changes from an excited state to a ground state, light is emitted.

The encapsulation member 200 may cover the display panel 100. That is, the encapsulation member 200 may cover the organic light emitting diode 30 formed on the display panel 100. The encapsulation member 200 may protect the organic light emitting diode 30 of the display panel 100 and prevent moisture from permeating the organic light emitting diode 30. The area of the encapsulation member 200 may be substantially equal to or smaller than the area of the display panel 100 and larger than the area of the organic light emitting diode 30.

The encapsulation member 200 may include a material that is substantially the same as that of the substrate member 110, but is not limited thereto. Accordingly, the encapsulation member 200 may include any material having excellent moistureproofing properties and excellent adhesive properties with regard to the first sealant 410 and the second sealant 420.

The first sealant 410 and the second sealant 420 may be interposed between the display panel 100 and the encapsulation member 200 and adhered to both the display panel 100 and the encapsulation member 200, respectively. That is, the first sealant 410 and the second sealant 420 seal off the space between the display panel 100 and the encapsulation member 200.

The first sealant 410 and the second sealant 420 may surround the organic light emitting diode 30 of the display panel 100. The first sealant 410 and the second sealant 420 may have a shape of a barrier. The second sealant 420 may be disposed between the first sealant 410 and the organic light emitting diode 30. That is, the first sealant 410 may be disposed outside of the second sealant 420.

The first sealant 410 and the second sealant 420 may each include glass frit. The fundamental component of glass frit includes paste that is a mixture of ceramic materials such as silicon dioxide and an organic binder. In the first exemplary embodiment, the glass frit may further include a transition metal such as iron (Fe), copper (Cu), vanadium (V), manganese (Mn), cobalt (Co), nickel (Ni), chrome (Cr), and neodymium (Nd). That is, the glass frit of the first exemplary embodiment is multicomponent-glass doped with a transition metal.

According to the first exemplary embodiment, the first sealant 410, the second sealant 420, the substrate member 110 of the display panel 100, and the encapsulation member 200 may include a similar material, such as a glass-like material. In this case, the substrate member 110 of the display panel 100, and the encapsulation member 200 may effectively adhere to each other through the first sealant 410 and the second sealant 420. However, the substrate member 110 of the display panel 100 may include glass frit without a transition metal.

The desiccant member 450 may be interposed between the first sealant 410 and the second sealant 420. The desiccant member 450 may be made by drying a liquid desiccant and activating the dried liquid desiccant. Herein, the liquid desiccant may be, for example, “DRYLOS®” of DuPont Company, U.S.

As shown in FIG. 2, the display device 901 includes the organic light emitting diode 30 disposed on the center and the first sealant 410 and the second sealant 420 may surround the organic light emitting diode 30. The desiccant member 450 may be interposed between the first sealant 410 and the second sealant 420.

With the above-described configuration, the display device 901 may effectively prevent moisture from entering the inside of the display device 901 and may prevent any moisture that does enter the inside of the display device 901 from permeating the organic light emitting diode 30.

The first sealant 410 and the second sealant 420 may each surround the organic light emitting diode 30 and seal off the space between the display panel 100 and the encapsulation member 200. Accordingly, even if one of the first sealant 410 and the second sealant 420 is damaged, the other of the first sealant 410 and the second sealant 420 may stably prevent moisture from permeating the organic light emitting diode 30.

The desiccant member 450 interposed between the first sealant 410 and the second sealant 420 may further prevent moisture from permeating the organic light emitting diode 30.

Accordingly, the quality deterioration of the display device 901 may be reduced and the durability of the display device 901 may be improved.

In the first exemplary embodiment, the display device 901 includes the desiccant member 450, but they are not limited thereto. Accordingly, the desiccant member 450 may be omitted in other exemplary embodiments. In this case, the first sealant 410 and the second sealant 420 may sufficiently prevent moisture from permeating the organic light emitting diode 30.

In a cutting process to form the display device 901, one of the first sealant 410 and the second sealant 420 may be damaged. Even so, the moisture-proof property of display device 901 may be sufficiently maintained because the display device 901 is sealed by both of the first sealant 410 and the second sealant 420.

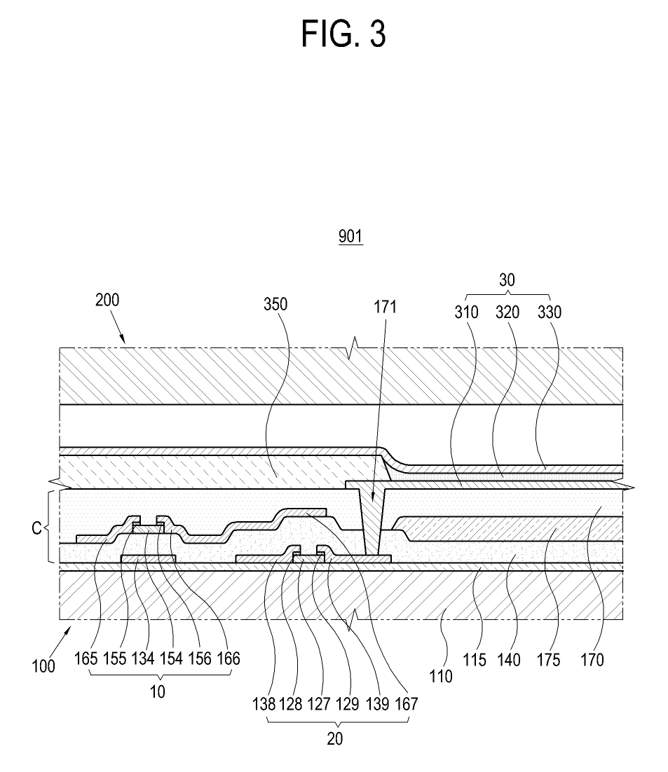

A structure of the display device 901 will be described in further detail with reference to FIG. 3. FIG. 2 shows an enlarged portion of the display device 901, which emits light to display an image.

The display panel 100 displays an image through a plurality of pixels. The pixel is a minimum unit to display an image. A switching thin film transistor 10, a driving thin film transistor 20, a capacitor (not shown), and organic light emitting diode 30 may be formed in one pixel.

Although it is not shown in the drawings, the display panel 100 further includes a gate line extending in one direction, a data line crossing the gate line, and a common power line.

The organic light emitting diode 30 includes the pixel electrode 310, the organic layer 320 formed on the pixel electrode 310, and the common electrode 330 formed on the organic layer 320. Herein, the pixel electrode 310 serves as a hole injection electrode (i.e., positive electrode) and the common electrode 330 serves as an electron injection electrode (i.e., negative electrode).

The switching thin film transistor 10 includes a switching gate electrode 134, a switching source electrode 165, a switching drain electrode 166, and a switching semiconductor layer 154. The driving thin film transistor 20 includes a driving gate electrode 167, a driving source electrode 138, a driving drain electrode 139, and a driving semiconductor layer 127.

The switching thin film transistor 10 is used as a switching element to select a pixel to emit light. The switching gate electrode 134 may be branched from the gate line. The switching source electrode 165 may be branched from the data line. The switching drain electrode 166 may be independently disposed and connected to the driving gate electrode 167.

The driving thin film transistor 20 applies a driving power to the pixel electrode 310 to cause light emission from the organic layer 320 of a selected organic light emitting diode 30.

The driving source electrode 138 of the driving thin film transistor 20 may be branched from a common power line (not shown). The driving drain electrode 139 may be connected to the pixel electrode 310 of the organic light emitting diode 30. The pixel electrode 310 may be connected to the driving drain electrode 139 through the contact hole 171.

Although it is not shown in the drawings, a pair of storage electrodes may be respectively connected to the common power line and the driving gate electrode 167. The storage electrodes may overlap each other to form a capacitor.

With the above-described configuration, the switching thin film transistor 10 may be driven by a gate voltage supplied through the gate line and may supply the data voltage to the driving thin film transistor 20. A voltage corresponding to the difference between the common voltage, which is supplied from the common power line to the driving thin film transistor 20, and the data voltage, which is supplied from the switching thin film transistor 10, may be stored into the capacitor (not shown). A current corresponding to the voltage stored in the capacitor (not shown) flows into the organic light emitting diode 30 through the driving thin film transistor 20 to emit light.

Hereinafter, the display panel 100 will be described according to its lamination order.

A buffer layer 115 may be formed on the substrate member 110. Herein, the buffer layer 115 may prevent an impurity of the substrate member 110 from penetrating therethrough and may provide a planar surface. In other exemplary embodiments, the buffer layer 115 may be omitted.

The driving semiconductor layer 127 may be formed on the buffer layer 115. The driving semiconductor layer 127 may include polysilicon.

The switching gate electrode 134, the driving source electrode 138, and the driving drain electrode 139 may be formed on the buffer layer 115 and the driving semiconductor layer 127. At least a portion of the driving source electrode 138 and at least a portion of the driving drain electrode 139 may overlap the driving semiconductor layer 127, respectively.

Driving ohmic contact layers 128 and 129 may be interposed between the driving semiconductor layer 127 and the driving source electrode 138 and between the driving semiconductor layer 127 and the driving drain electrode 139, respectively. The driving ohmic contact layers 128 and 129 may include n+ polysilicon in which an n-type impurity is highly doped. The driving ohmic contact layers 128 and 129 may reduce the contact resistance between the driving semiconductor layer 127 and the driving source electrode 138 and between the driving semiconductor layer 127 and the driving drain electrode 139, respectively.

An insulating layer 140 may be formed on the switching gate electrode 134, the driving source electrode 138, and the driving drain electrode 139. The switching semiconductor layer 154 is formed on the insulating layer 140. The switching semiconductor layer 154 may include an amorphous silicon layer.

The switching source electrode 165 and the switching drain electrode 166 may be formed on the insulating layer 140 and the switching semiconductor layer 154, and the driving gate electrode 167 may be formed on the insulating layer 140. Herein, the driving gate electrode 167 may be connected to the switching drain electrode 166. At least a portion of the switching source electrode 165 and at least a portion of the switching drain electrode 166 may overlap the switching semiconductor layer 154, respectively.

In addition, switching ohmic contact layers 155 and 156 may be interposed between the switching semiconductor layer 154 and the switching source electrode 165 and between the switching semiconductor layer 154 and the switching drain electrode 166, respectively. The switching ohmic contact layers 155 and 156 may include n+ amorphous silicon in which an n-type impurity is highly doped. The switching ohmic contact layers 155 and 156 may reduce the contact resistance between the switching semiconductor layer 154 and the switching source electrode 165 and between the switching semiconductor layer 154 and the switching drain electrode 166, respectively.

A passivation layer 170 may be formed on the switching source electrode 165, the switching drain electrode 166, and the driving gate electrode 167. The passivation layer 170 may act as a planarization layer.

The passivation layer 170 may be formed with a contact hole 171 exposing the driving drain electrode 139. In the contact hole 171, the insulating layer 140 is also removed.

A pixel electrode 310 may be formed on the passivation layer 170. The pixel electrode 310 may be connected to the driving drain electrode 139 through the contact hole 171.

The pixel electrode 310 may be formed of a transparent conductive material such as indium tin oxide (ITO) or indium zinc oxide (IZO).

A pixel definition layer 350 may be formed on the pixel electrode 310. The pixel definition layer 350 may be formed with an opening exposing the pixel electrode 310. That is, the pixel definition layer 350 may substantially define each pixel in the display device 100.

An organic layer 320 may be formed on the portion of the pixel electrode 310 exposed by the opening of the pixel definition layer 350. The common electrode 330 may cover the pixel definition layer 350 and the organic layer 320. The pixel electrode 310, the organic layer 320, and the common electrode 330 may form the organic light emitting diode 30.

The organic layer 320 may include a low molecular weight organic material or a polymer material. The organic layer 320 may include multiple layers including a hole-injection layer (HIL), a hole-transporting layer (HTL), an emission layer, an electron-transporting layer (ETL), and an electron-injection layer (EIL). That is, the HIL may be disposed on the pixel electrode 310, which is a positive electrode, and the HTL, the emission layer, the ETL, and the EIL may be sequentially stacked on the HIL.

The emission layer emits light. In a first exemplary embodiment of the present invention, the display device 901 may further includes a color filter 175 disposed under the passivation layer 170 and overlapping the organic layer 320. Accordingly, light emitted from the organic layer 320 has a color. In each pixel, a color filter 175 having one of red, blue, and green colors is disposed, but the color filter 175 is not limited thereto. Accordingly, the color filter 175 may include another color. Also, a white pixel may be formed if a portion of the plurality of the organic layer 320 does not overlap the color filter 175.

In other exemplary embodiment, the color filter may be omitted, and the emission layer may emit one of white light, red light, blue light, and green light.

In the first exemplary embodiment, the pixel electrode 310 is the positive electrode and the common electrode 330 is the negative electrode, but they are not limited thereto. That is, the pixel electrode 310 may be the negative electrode and the common electrode 330 may be the positive electrode. In this case, the organic layer 320 may be formed by sequentially stacking the EIL, the ETL, the emission layer, the HTL, and the HIL on the pixel electrode 310.

In the first exemplary embodiment, the thin film transistors 10 and 20 are not limited to above-described structure. The thin film transistors 10 and 20 may have various structures different from the above-described structure.

The display panel 100 may be covered with the encapsulation member 200 and sealed by the first sealant 410, the second sealant 420, and the desiccant member 450.

With the above-described configuration, the display device 901 may prevent moisture from permeating the organic light emitting diode 30. Accordingly, the quality deterioration of the display device 901 may be reduced, and the durability of the display device 901 may be improved.

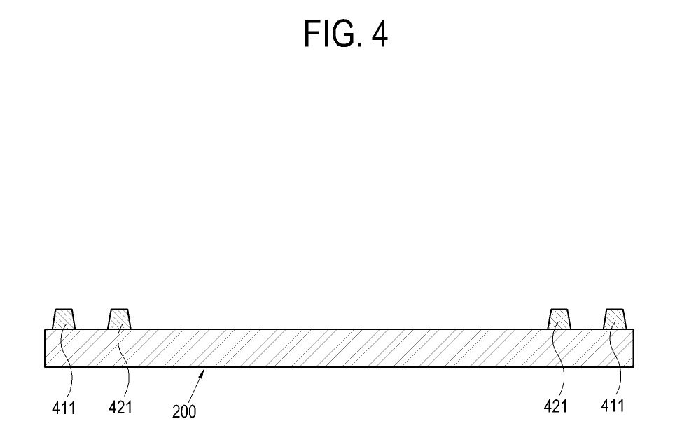

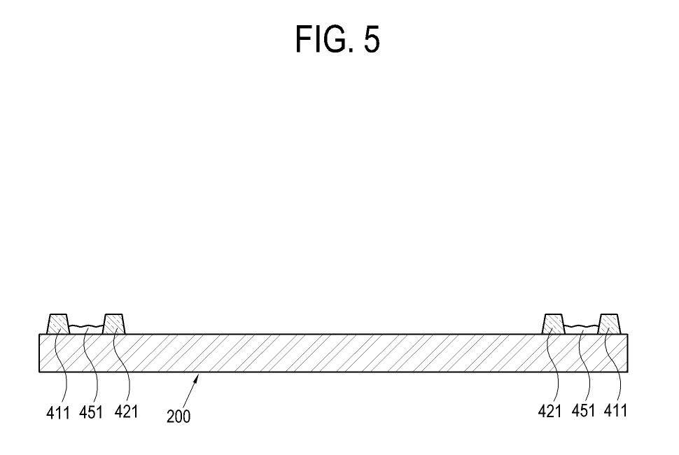

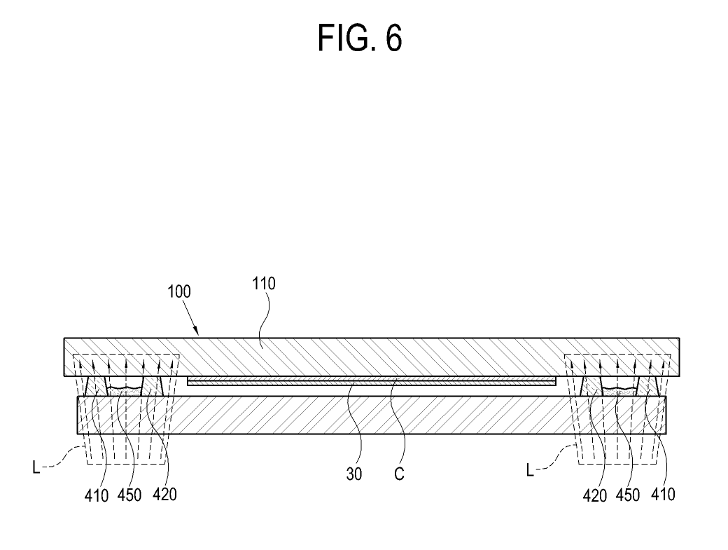

A manufacturing method of the display device 901 according to the first exemplary embodiment of the present invention will be described in further detail with reference to FIG. 4, FIG. 5, and FIG. 6.

As shown in FIG. 4, a first intermediate sealant 411 and a second intermediate sealant 421 may be formed on a periphery of the encapsulation member 200 and may each have a loop shape. The first intermediate sealant 411 may be disposed outside the second intermediate sealant 421.

The first intermediate sealant 411 and the second intermediate sealant 421 may be formed on the encapsulation member 200, but they are not limited thereto. Accordingly, the first intermediate sealant 411 and the second intermediate sealant 421 may be formed on the display panel 100.

The first intermediate sealant 411 and the second intermediate sealant 421 may be formed by applying glass frit to the periphery of the encapsulation member 200 and heating the glass frit to a temperature in the range of 150° C. to 500° C. The glass frit may be applied to the encapsulation member 200 through a dispensing method or screen printing method.

The first intermediate sealant 411 and the second intermediate sealant 421 may not be completely hardened at this time, but may later be hardened to have a stable shape. In this process, unnecessary organic material and impurities may be removed from the first intermediate sealant 411 and the second intermediate sealant 421.

As shown in FIG. 5, an intermediate desiccant member 451 may be formed between the first intermediate sealant 411 and the second intermediate sealant 421 through a dispensing method or a screen printing method. Herein, the intermediate desiccant member 451 may be a liquid desiccant. The liquid desiccant may be, for example, “DRYLOS®” of DuPont Company, U.S. The formed liquid desiccant may be dried at a temperature ranging from 40° C. to 90° C.

As shown in FIG. 6, the encapsulation member 200 on which the first intermediate sealant 411, the second intermediate sealant 421, and the intermediate desiccant member 451 are formed may cover the display panel 200 including the organic light emitting diode 30.

Then, the first sealant 410 and the second sealant 420 may be formed by providing the first intermediate sealant 411 and the second intermediate sealant 421 with an energy source L. In this process, the first sealant 410 and the second sealant 420 may each adhere to both the display panel 100 and the encapsulation member 200. Accordingly, the space between the display panel 100 and the encapsulation member 200 may be sealed off.

While the first intermediate sealant 411 and the second intermediate sealant 421 are being provided with an energy source L, the desiccant member 450 may be formed by providing the intermediate desiccant member 451 with the energy source L.

The energy source L may include a laser. That is, the first sealant 410, the second sealant 420, and the desiccant member 450 may be formed by applying a laser to the first intermediate sealant 411, the second intermediate sealant 421, and the intermediate desiccant member 451, respectively.

The first sealant 410 and the second sealant 420 may include multicomponent-glass doped with a transition metal such as iron (Fe), copper (Cu), vanadium (V), manganese (Mn), cobalt (Co), nickel (Ni), chrome (Cr), or neodymium (Nd). Due to the transition metal component, the first intermediate sealant 411 and the second intermediate sealant 421 may have an enhanced decalescence property. Accordingly, the first intermediate sealant 411 and the second intermediate sealant 421 may absorb the laser efficiently and may be changed to the first sealant 410 and the second sealant 420 easily. Herein, the first sealant 410 and the second sealant 420 may seal off the space between the display panel 100 and the encapsulation member 200. However, the substrate member 110 of the display panel 100 may not include a transition metal and therefore, the substrate member 110 may absorb the laser less than the first intermediate sealant 411 and the second intermediate sealant 421. Accordingly, it may be possible to avoid damaging various circuits of the display panel 100 when the substrate member 110 is heated.

The desiccant member 450, the first sealant 410, and the second sealant 420 may be formed under a vacuum, but they are not limited thereto. In other exemplary embodiments, the desiccant member 450, the first sealant 410, and the second sealant 420 may be formed under an inert gas atmosphere.

With the above-described manufacturing method, a display device 901 that may prevent moisture from permeating the organic light emitting diode 30 is provided. Accordingly, deterioration of the quality of the display device 901 may be reduced and the durability of the display device 901 may be improved.

In a cutting process to form display device 901, one of the first sealant 410 and the second sealant 420 may be damaged. Even so, the moisture-proof property of display device 901 may be sufficiently maintained because the display device 901 may be sealed by both the first sealant 410 and the second sealant 420.

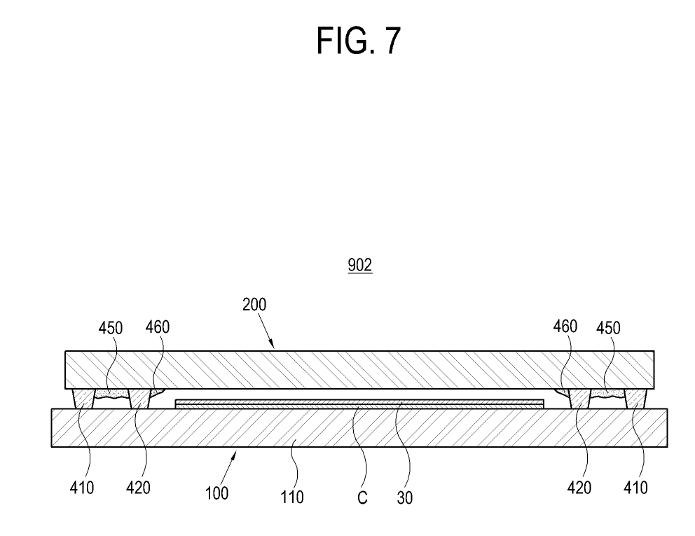

Referring to FIG. 7, the second exemplary embodiment of the present invention will be described.

As shown in FIG. 7, the display device 902 further may include an auxiliary desiccant member 460 disposed between the second sealant 420 and the organic light emitting diode 30.

With the above-described configuration, the display device 902 may also effectively prevent moisture from permeating the organic light emitting diode 30. Accordingly, deterioration of the quality of the display device 902 may be further reduced, and the durability of the display device 902 may be further improved.

As described above, according to the exemplary embodiments of the present invention, the durability of the display device may be improved. That is, the display device may effectively prevent moisture from permeating the organic light emitting diode.

In addition, the first sealant and the second sealant may surround the organic light emitting diode and seal off the space between the display panel and the encapsulation member. Accordingly, even if one of the first sealant and the second sealant is damaged, the other of the first sealant and the second sealant may seal off the space between the display panel and the encapsulation member and stably prevent moisture from permeating the organic light emitting diode.

In addition, the above-described manufacturing method of the display device may be provided.

It will be apparent to those skilled in the art that various modifications and variations can be made in the present invention without departing form the spirit or scope of the invention. Thus, it is intended that the present invention cover the modifications and variations of this invention provided they come within the scope of the appended claims and their equivalents.

What is claimed is:

1. A display device, comprising:
a display panel comprising an organic light emitting diode (OLED);
an encapsulation member covering the display panel;
a first sealant disposed between the display panel and the encapsulation member and surrounding the organic light emitting diode; and
a second sealant disposed between the first sealant and the organic light emitting diode and surrounding the organic light emitting diode.

2. The display device of claim 1, wherein the first sealant and the second sealant each comprise glass frit.

3. The display device of claim 2, wherein the glass frit comprises a ceramic material and an organic binder.

4. The display device of claim 3, wherein the glass frit is multicomponent-glass doped with iron (Fe), copper (Cu), vanadium (V), manganese (Mn), cobalt (Co), nickel (Ni), chrome (Cr), or neodymium (Nd).

5. The display device of claim 2, further comprising a desiccant member disposed between the first sealant and the second sealant.

6. The display device of claim 5, wherein the desiccant member comprises a dried and activated liquid desiccant.

7. The display device of claim 5, further comprising an auxiliary desiccant member disposed between the second sealant and the organic light emitting diode.

8. A display device manufacturing method, comprising:
preparing a display panel comprising an organic light emitting diode (OLED);
preparing an encapsulation member;
forming a first intermediate sealant and a second intermediate sealant on one of the display panel and the encapsulation member, the first intermediate sealant and the second intermediate sealant having loop shapes and one of the first intermediate sealant and the second intermediate sealant surrounding the other;
adjoining the other of the display panel and the encapsulation member to the first intermediate sealant and the second intermediate sealant; and
forming a first sealant and a second sealant by providing the first intermediate sealant and the second intermediate sealant with energy from an energy source, the first sealant and the second sealant being adhered to the display panel and the encapsulation member.

9. The display device manufacturing method of claim 8, wherein the first intermediate sealant and the second intermediate sealant comprise glass frit, the glass frit comprising a ceramic material and an organic binder, and
wherein the first intermediate sealant and the second intermediate sealant may be formed by heating the glass frit to a temperature ranging from 150° C. to 500° C.

10. The display device manufacturing method of claim 9, wherein the glass frit is multicomponent-glass doped with iron (Fe), copper (Cu), vanadium (V), manganese (Mn), cobalt (Co), nickel (Ni), chrome (Cr), or neodymium (Nd).

11. The display device manufacturing method of claim 9, wherein the first intermediate sealant and the second intermediate sealant are formed by one of a dispensing method and a screen printing method.

12. The display device manufacturing method of claim 8, wherein the energy source comprises a laser.

13. The display device manufacturing method of claim 9, further comprising forming an intermediate desiccant member between the first intermediate sealant and the second intermediate sealant; and
forming an activated desiccant member by providing the intermediate desiccant member with energy from the energy source.

14. The display device manufacturing method of claim 13, wherein the energy source comprises a laser.

15. The display device manufacturing method of claim 13, wherein the first sealant, the second sealant, and the activated desiccant are formed simultaneously.

16. The display device manufacturing method of claim 15, wherein the first sealant, the second sealant, and the activated desiccant member are formed under a vacuum.

17. The display device manufacturing method of claim 15, wherein the first sealant, the second sealant, and the activated desiccant member are formed in an inert gas atmosphere.

18. The display device manufacturing method of claim 13, wherein the intermediate desiccant member comprises a liquid desiccant.

19. The display device manufacturing method of claim 18,
wherein the intermediate desiccant member is formed by one of a dispensing method and a screen printing method.
